(19) United States
(12) Patent Application Publication
(10) Pub. No.: US 2009/0023230 A1
(43) Pub. Date: Jan. 22, 2009

(54) METHODS AND APPARATUS FOR DEPOSITING AN ANTI-REFLECTION COATING

(75) Inventor: Michael C. Smayling, Fremont, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/176,544

(22) Filed: Jul. 21, 2008

Related U.S. Application Data
(60) Provisional application No. 60/951,000, filed on Jul. 20, 2007.

(51) Int. Cl. H01L 21/66

(52) U.S. Cl. 438/16

(57) ABSTRACT

Systems, methods, and apparatus are provided for depositing an anti-reflection film on a substrate. A substrate is transported to a metrology tool. A characteristic of the substrate is measured, via the metrology tool. A recipe for an anti-reflection film is determined, based on the measured characteristic. The substrate is transported from the metrology tool to a process chamber. The recipe is employed to form an anti-reflection film on the substrate within the process chamber. Numerous other aspects are provided.

### CROSS-REFERENCE TO RELATED APPLICATION

The present invention claims priority to U.S. Provisional Patent Application No. 60/951,000, filed Jul. 20, 2007, and entitled “METHODS AND APPARATUS FOR DEPOSITING AN ANTI-REFLECTION COATING” which is hereby incorporated by reference herein for all purposes.

### FIELD OF THE INVENTION

The present invention relates to semiconductor device manufacturing, and more particularly to methods and apparatus for depositing an anti-reflection coating on a substrate.

### BACKGROUND OF THE INVENTION

During semiconductor device processing, various material layers may be formed on a substrate (e.g., a silicon substrate, a glass plate for flat panel displays, a polymer substrate, etc.). The multiple layers of film may be referred to as a film stack.

A film stack formed on a substrate may have reflecting properties that adversely affect other processes to be performed on the substrate, such as photolithography processes. An anti-reflection film or coating may be deposited on the film stack to improve the reflective properties of the film stack. Improved methods and apparatus for forming such anti-reflection coatings are desired.

### SUMMARY OF THE INVENTION

In a first aspect of the invention, a method is provided for depositing an anti-reflection coating on a substrate. The method includes the steps of (1) transporting a substrate to a metrology tool; (2) measuring, via the metrology tool, a characteristic of the substrate; (3) determining a recipe for an anti-reflection film based on the measured characteristic; (4) transporting the substrate from the metrology tool to a process chamber; and (5) employing the recipe to form an anti-reflection film on the substrate within the process chamber.

In a second aspect of the invention, an apparatus is provided for depositing an anti-reflection coating on a substrate. The apparatus includes a metrology tool adapted to measure a characteristic of the substrate. A simulator, operatively coupled to the metrology tool, is adapted to determine and/or simulate an anti-reflection film for the substrate based on the measured characteristic. A controller, which may include and/or which is operatively coupled to the simulator, causes a recipe to be performed at a process chamber based on the simulator results so that an anti-reflection film is formed on the substrate.

Other features and aspects of the present invention will become more fully apparent from the following detailed description, the appended claims and the accompanying drawings.

### BRIEF DESCRIPTION OF THE DRAWINGS

FIG. 1 is a schematic diagram of a system for depositing an anti-reflection coating on a substrate in accordance with an embodiment of the present invention.

FIG. 2 is a flowchart illustrating an exemplary method for depositing an anti-reflection coating on a substrate in accordance with an embodiment of the present invention.

### DETAILED DESCRIPTION

The present invention provides methods and apparatus for depositing an anti-reflection coating on a substrate to aid in fabrication of devices on the substrate. For example, use of the present invention may reduce and/or minimize reflectance of a film stack, improving photolithography resolution and reducing standing wave formation. The present invention uses information determined from a metrology or other tool to develop or select a processing recipe for a substrate. The substrate is then transported to a processing chamber that has been adapted to execute the recipe developed for the substrate. In this manner, data derived from performing metrology on the substrate is fed forward to the processing system from the metrology tool so that, for example, an anti-reflective coating specific to the substrate may be applied to the substrate according to a recipe selected or determined based on measured characteristics of the specific substrate.

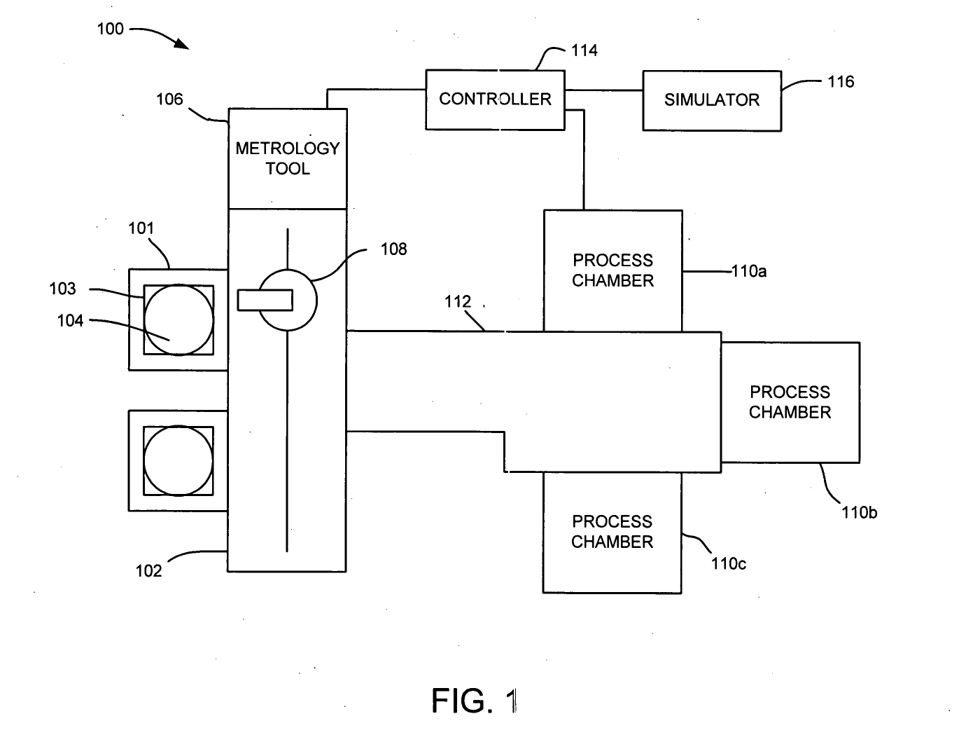

Turning to FIG. 1 of the present invention, a system 100, is provided. The system 100 may include at least one loadport 101 coupled to a factory interface 102. A substrate carrier 103 containing one or more substrates 104, may be positioned on the loadport 101. As described above, a film stack of a plurality of deposited, grown or otherwise formed layers (not shown) may be formed on the substrate 104.

The system 100 may also include a metrology tool 106. In at least one embodiment, the metrology tool 106 may be coupled to the factory interface 102, and a robot arm 108 positioned within the factory interface 102 may unload a substrate 104 from the substrate carrier 103 and place the substrate 104 in the metrology tool 106. Other metrology tool locations may be used. The metrology tool 106 may measure one or more characteristics of the substrate 104, including, for example, one or more optical properties of the film stack (not shown) formed on the substrate 104. The measured optical properties may include the reflectivity of the film stack and/or the thickness of the film stack. Other optical properties may be measured. Any suitable metrology tool may be employed. For example, a reflectometry-based thickness measurement tool such as a NanoSpec 9000 or 9000B measurement tool manufactured by Nanometrics may be used, as may other metrology tools.

One or more process chambers 110a-c are shown coupled to the factory interface 102 via a transfer chamber 112. Other numbers of process chambers may be used. In at least one embodiment of the invention, one or more of the process chambers 110a-c is configured to deposit an anti-reflection film on a substrate (as described below). Any suitable anti-reflection film may be used.

The system 100 may further include a controller 114 coupled to the metrology tool 106. The controller 114 may be hardwired or wirelessly coupled to the metrology tool 106. In some embodiments, the controller 114 may be coupled to and/or otherwise communicate with and/or control operation of one or more of the process chambers 110a-c as described further below. The controller 114 may be a microcomputer, microprocessor, logic circuit, a combination of hardware and software, or the like.

The system 100 may also include an anti-reflection film simulator 116 which may be separate from or a part of the controller 114. For example, the anti-reflection film simulator 116 may include computer program code stored in a memory of the controller 114 or in memory external to the controller 116. Alternatively, the simulator 116 may be a separate computer or other controller that communicates with the controller 114.

In operation, the substrate carrier 103 is delivered to the loadport 101 of the factory interface 102. The robot 108 of the factory interface 102 unloads a substrate 104 from the substrate carrier 103 and transfers the substrate 104 to the metrology tool 106. At the metrology tool 106, one or more characteristics of the substrate 104 are measured, such as reflectivity and/or thickness, and are communicated to the controller 114. Based on the measured characteristic(s) of the substrate 104, the controller 114 employs the simulator 116 to determine a desired (e.g., optimal) anti-reflection film for the substrate 104 (e.g., so as to reduce or minimize reflection from the substrate 104 during subsequent photolithographic processing). For example, the controller 114 and/or simulator 116 may determine the thickness, type or other information for an anti-reflection film to be formed on the substrate 104. In some embodiments, based on the results of the simulator 116, the controller 114 may determine a process recipe for forming an anti-reflection film in one or more of the process chambers 110a-c. For example, the controller 114 may specify the source materials, flow rates, deposition time, temperature, etc., for an anti-reflection film formation process within any of the process chambers 110a-c. In at least one embodiment, the controller 114 may control operation of a process chamber during anti-reflection film formation within the process chamber. The anti-reflection film simulator 116 may simulate the behavior of and/or determine an appropriate anti-reflection film for the substrate 104 to reduce and/or minimize reflectance, based on the measurements communicated to the controller 114 by the metrology tool 106.

Following measurement within the metrology tool 106, the substrate 104 may be transferred to one of the process chambers 110a-c via the robot 108 of the factory interface 102, and a transfer chamber robot (not shown). The desired anti-reflection film then may be deposited on the substrate 104 (e.g., using the recipe provided by the controller 114). In this manner, an anti-reflection film is provided that is based on the actual characteristics of the substrate 104.

After the substrate 104 is processed, the substrate 104 may be transferred to another process chamber for further processing and/or returned to the substrate carrier 103 at the loadport 101.

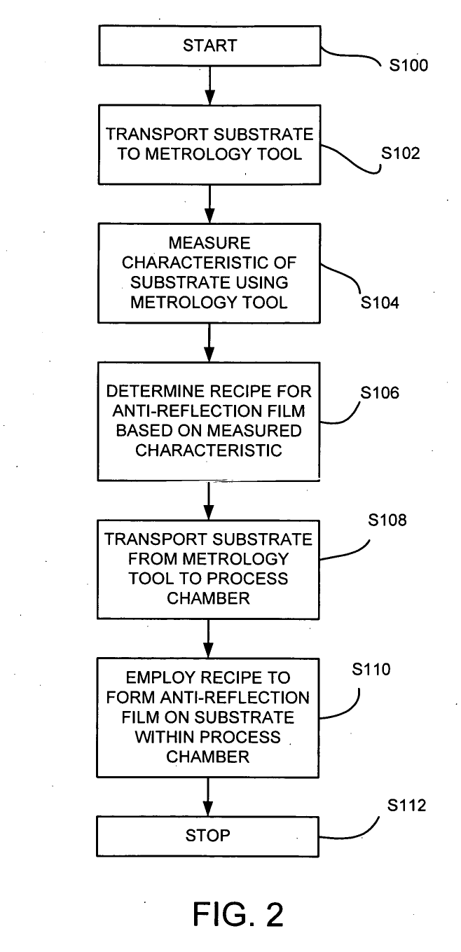

Turning to FIG. 2, a flowchart illustrating an exemplary method for depositing an anti-reflection coating on a substrate is depicted. In step S100, the process begins. Then in step S102, a substrate is transported to a metrology tool. The metrology tool measures at least one characteristic of the substrate in step S104. As described above, in some embodiments, the characteristic may be of an optical nature and may include reflectivity or thickness of a film stack formed on a surface of the substrate. In step S106, a recipe for an anti-reflection film is determined, based on the measured characteristic(s). The substrate is then transported from the metrology tool to a process chamber in step S108. In step S110 the recipe is used to apply an anti-reflection film to the substrate, while the substrate is in the process chamber. In step S112, the method ends.

In some embodiments, the above-described methods may be embodied as program instructions adapted to be executed by a processor within the controller 114. The controller may also include a memory adapted to store program instructions embodying the above-described methods.

Use of the present invention may reduce and/or minimize reflectance of a film stack, improving photolithography resolution and reducing standing wave formation.

The foregoing description discloses only exemplary embodiments of the invention. Modifications of the above disclosed apparatus and methods which fall within the scope of the invention will be readily apparent to those of ordinary skill in the art. In some embodiments, the apparatus and methods of the present invention may be applied to semiconductor device processing and/or electronic device manufacturing.

Accordingly, while the present invention has been disclosed in connection with exemplary embodiments thereof, it should be understood that other embodiments may fall within the spirit and scope of the invention, as defined by the following claims.

The invention claimed is:

1. A method for depositing an anti-reflection film on a substrate comprising:
transporting a substrate to a metrology tool;
measuring, via the metrology tool, a characteristic of the substrate;
determining a recipe for an anti-reflection film based on the measured characteristic;
transporting the substrate from the metrology tool to a process chamber; and
employing the recipe to form an anti-reflection film on the substrate within the process chamber.

2. The method of claim 1, further comprising:
measuring, via the metrology tool, at least one optical property of the substrate.

3. The method of claim 1, further comprising:
measuring, via the metrology tool, at least one of a reflectivity and a thickness of the substrate.

4. The method of claim 1, further comprising:
providing information regarding the characteristic to a controller.

5. The method of claim 1 wherein determining a recipe includes using the measured characteristic to simulate a behavior of an anti-reflection film applied to the substrate.

6. The method of claim 5 further comprising selecting a recipe based on the simulated behavior of the anti-reflection film.

7. The method of claim 1 wherein determining a recipe includes transmitting the measured characteristic to a controller adapted control the process chamber.

8. A controller for depositing an anti-reflection film on a substrate comprising:
a memory;
a processor coupled to the memory and adapted to execute program instructions including:
direct a transfer robot to transport a substrate to a metrology tool;
direct the metrology tool to measure a characteristic of the substrate;
determine a recipe for an anti-reflection film based on the measured characteristic;
direct the transfer robot to transport the substrate from the metrology tool to a process chamber; and
direct the process chamber to employ the recipe to form an anti-reflection film on the substrate within the process chamber.

9. The controller of claim 8 wherein the processor is further adapted to execute a program instruction to direct the metrology tool to measure at least one optical property of the substrate.

10. The controller of claim 8 wherein the processor is further adapted to execute a program instruction to direct the metrology tool to measure at least one of a reflectivity and a thickness of the substrate.

11. The controller of claim 8 wherein the processor is further adapted to execute a program instruction to receive information regarding the characteristic.

12. The controller of claim 8 wherein the processor is further adapted to execute a program instruction to use the measured characteristic to simulate a behavior of an anti-reflection film applied to the substrate.

13. The controller of claim 12 wherein the processor is further adapted to execute a program instruction to select a recipe based on the simulated behavior of the anti-reflection film.

14. The controller of claim 8 wherein the processor is further adapted to execute a program instruction to control the process chamber based on the measured characteristic.

15. A system for depositing an anti-reflection film on a substrate comprising:
a controller;
a process chamber coupled, to and operable by, the controller;
a transfer robot coupled, to and operable by, the controller; and
a metrology tool coupled, to and operable by, the controller,
wherein the controller is adapted to direct the metrology too to measure a characteristic of a substrate, direct the transfer robot to place the substrate in the process chamber, and direct the process chamber to deposit an anti-reflection film on the substrate using a recipe determined based on the measured characteristic of the substrate.

16. The system of claim 15 further comprising a simulator, operatively coupled to the metrology tool and adapted to simulate an anti-reflection film for the substrate based on the measured characteristic.

17. The system of claim 16 wherein the controller is further adapted to receive the measured characteristic from the metrology tool.

18. The system of claim 17 wherein the controller is further adapted to transmit the measured characteristic to the simulator.

19. The system of claim 18 wherein the controller is further adapted to determine the recipe based on output from the simulator.

20. The system of claim 19 wherein the metrology tool is adapted to measure at least one optical property of the substrate.
